(19) United States
(12) Patent Application Publication
(10) Pub. No.: US 2024/0396521 A1
(43) Pub. Date: Nov. 28, 2024

(54) PIEZOELECTRIC VIBRATION DEVICE

(71) Applicant: DAISHINKU CORPORATION, Hyogo (JP)

(72) Inventors: Kazuya FUJINO, Hyogo (JP); Manabu OHNISHI, Hyogo (JP)

(73) Assignee: DAISHINKU CORPORATION, Hyogo (JP)

(21) Appl. No.: 18/696,562

(22) PCT Filed: Aug. 31, 2022
(86) PCT No.: PCT/JP2022/032821

§ 371 Date: Mar. 28, 2024

(30) Foreign Application Priority Data
Sep. 30, 2021 (JP) 2021-161145

(51) Int. Cl. H03H 9/10; H03H 9/05; H03H 9/19

(52) U.S. Cl. CPC H03H 9/1021; H03H 9/0542; H03H 9/19

(57) ABSTRACT

A piezoelectric vibration device that can be firmly joined to an external substrate in a position as close as possible to the external substrate. A piezoelectric vibration device in which at least an oscillator and an integrated circuit element on a substrate on a first mounting surface and an external connection terminal electrically connected to an external substrate on a second mounting surface extending in parallel to the one of the principal surfaces. The substrate includes a recessed portion in the second mounting surface. The external connection terminal is arranged in the recessed portion and is configured such that a gap is provided between an outer edge of the external connection terminal and a side surface of the recessed portion.

### TECHNICAL FIELD

The present invention relates to a piezoelectric vibration device.

### BACKGROUND ART

A piezoelectric vibration device includes, for example, a crystal oscillator using a crystal vibration piece. The crystal oscillator includes the crystal vibration piece that is a piezoelectric element, a holding member that holds the crystal vibration piece, and a lid member that seals the holding member. The crystal oscillator is configured such that the crystal vibration piece is held in the holding member having a box shape and formed of an insulator, such as ceramic. The crystal oscillator is configured such that the crystal vibration piece in the holding member is sealed with the lid member in a state where an electrode of the crystal vibration piece and an electrode of the holding member are joined to each other.

The piezoelectric vibration device described above is configured such that the holding member having a box shape and the lid member are superimposed, so that the piezoelectric vibration device has an increased thickness. Therefore, there have been known piezoelectric oscillators configured such that a vibrating portion including a first excitation electrode and a second excitation electrode, and a piezoelectric vibration plate connected to the vibrating portion via a connection portion and including an outer frame portion that surrounds the vibrating portion, are sealed with a sealing member. Such a piezoelectric oscillator having a stacked structure in which the piezoelectric vibration plate including the vibrating portion is sealed with the sealing member as described above can be formed such that a thickness of the piezoelectric oscillator itself is reduced.

As sizes of various electronic devices have been reduced, reduction in size of package in piezoelectric vibration devices configured such that the above-described piezoelectric oscillator and an integrated circuit element are mounted on a substrate is required. Thus, there have been known piezoelectric vibration devices configured such that the above-described piezoelectric oscillator having a stacked structure and the integrated circuit element are mounted on the substrate. For example, a piezoelectric vibration device described in Patent Document 1 is configured such that a crystal oscillator in which a first sealing member, a second sealing member, and a crystal vibration plate with excitation electrodes formed on both principal surfaces thereof are stacked and an electronic component element are mounted on a function portion that is a substrate connected to an external substrate.

### CITATION LIST

### Patent Document

Patent Document 1: Japanese Patent Application Publication No. 2015-139053

### SUMMARY OF INVENTION

### Technical Problem

In the piezoelectric vibration device described in Patent Document 1, a crystal oscillator and an electronic component element mounted on one of principal surfaces of the function portion are electrically connected to a mounting surface of the external substrate via the function portion. The one of the principal surfaces of the function portion includes a circuit pattern via which the crystal oscillator and the electronic component element are electrically connected to each other. The other one of the principal surfaces of the function portion includes an external connection terminal electrically connected to the external substrate.

The external connection terminal of the function portion is joined to a connection terminal of the external substrate by a solder or the like. That is, the function portion is joined to the external substrate in a state where the external connection terminal, the solder, and the connection terminal of the external substrate are stacked on the mounting surface of the external substrate. Furthermore, the crystal oscillator having a stacked structure is mounted on the function portion. In a piezoelectric vibration device in which, as in the function portion, an external connection terminal is formed on an outer bottom surface of a substrate connected to an external substrate, an entire height thereof is increased, so that a moment generated due to an impact, a vibration, or the like from outside is increased. That is, in the piezoelectric vibration device, a force that is generated by the moment and causes the external connection terminal to be separated from the connection terminal of the external substrate increases as the entire height increases.

It is therefore an object of the present invention to provide a piezoelectric vibration device that can be firmly joined to an external substrate in a position as close as possible to the external substrate.

### Solution to Problem

The inventors of the present invention studied a piezoelectric vibration device that is less likely to be separated from an external connection terminal even when vibration, an impact, or the like is applied. As a result of intensive studies, the inventors arrived at a configuration below.

A piezoelectric vibration device according to the present invention is a piezoelectric vibration device comprising: an insulating substrate that includes a wiring pattern including a plurality of pads on one of a pair of principal surfaces, and an external connection terminal electrically connected to the wiring pattern and electrically connected to an external substrate on the other one of the principal surfaces extending in parallel to the one of the principal surface; and at least a piezoelectric oscillator and an integrated circuit element including an oscillation circuit that are mounted on the insulating substrates. The insulating substrate includes a recessed portion in the other one of the principal surfaces. The external connection terminal is arranged in the recessed portion and is configured such that a gap is provided between an outer edge of the external connection terminal and a side surface of the recessed portion.

In the configuration described above, the external connection terminal is arranged in the recessed portion of the insulating substrate, so that a protrusion amount from the other one of the principal surfaces of the insulating substrate can be suppressed. Therefore, the piezoelectric vibration device is joined to the external substrate at a closer position to the external substrate than in a case where the external connection terminal is not arranged in the recessed portion. That is, the piezoelectric vibration device can be configured to have a smaller entire height than in a case where the external connection terminal is not arranged in the recessed portion. Moreover, in joining the piezoelectric vibration device to the external substrate, a joining material, such as a solder, that joins the external connection terminal to the external substrate enters the gap between the side surface of the recessed portion and an end surface including the outer edge of the external connection terminal in the insulating substrate. Therefore, the external connection terminal is arranged such that not only a joining surface that is joined to the external connection terminal but also the end surface of the external connection terminal is joined to the external connection terminal by the joining material. Thus, the piezoelectric vibration device can be firmly joined to the external substrate in a position as close as possible to the external substrate.

In another aspect, the piezoelectric vibration device of the present invention preferably has the following configuration. The external connection terminal is arranged in the recessed portion with a predetermined space from an outer edge of the recessed portion provided, when viewed in a perpendicular direction to the other one of the principal surfaces.

In the configuration described above, the external connection terminal is arranged such that a portion of a bottom surface of the recessed portion having a predetermined width from the outer edge of the recessed portion is exposed so as to surround the external connection terminal when viewed in the perpendicular direction to the other one of the principal surfaces. Therefore, not only the joined surface of the external connection terminal is connected to the external substrate by the joining material, but also the end surface of the external connection terminal and the bottom surface of the recessed portion are connected to the external substrate. Thus, the piezoelectric vibration device can be firmly joined to the external substrate in a position as close as possible to the external substrate.

In another aspect, the piezoelectric vibration device of the present invention preferably has the following configuration. A thickness from the one of the principal surfaces to a joined surface that is electrically connected to the external substrate in the external connection terminal is less than a thickness from the one of the principal surfaces to the other one of the principal surfaces.

In the configuration described above, the joined surface that is connected to the external substrate does not protrude from the other one of the principal substrate of the insulating substrate in the external connection terminal. Therefore, the piezoelectric vibration device is joined to the external substrate at a closer position to the external substrate than in a case where the external connection terminal is arranged on the other one of the principal surfaces. Thus, the piezoelectric vibration device can be firmly joined to the external substrate in a position as close as possible to the external substrate.

In another aspect, the piezoelectric vibration device of the present invention preferably has the following configuration. The insulating substrate is configured such that at least one of the piezoelectric oscillator or the integrated circuit element on the one of the principal surfaces is partially or entirely covered with resin.

In the configuration described above, the piezoelectric vibration device is configured such that at least one of the piezoelectric oscillator or the integrated circuit element is partially or entirely molded with resin together with the insulating substrate, and therefore, at least one of the piezoelectric oscillator or the integrated circuit element can be protected from an impact and a vibration from outside. Moreover, a rigidity of the insulating substrate is increased by resin molding, and therefore, the external connection terminal is less likely to be deflected due to an impact and a vibration. Thus, the piezoelectric vibration device can be firmly joined to the external substrate.

In another aspect, the piezoelectric vibration device of the present invention preferably has the following configuration. The insulating substrate is configured such that a portion of an internal wiring electrically connecting the wiring pattern and the external connection terminal is not covered with a base material of the insulating substrate and is exposed, the portion of the internal wiring being located at the other one of the principal surfaces.

In the configuration described above, the piezoelectric oscillator is configured such that a portion of the internal wiring that connects the wiring pattern of the one of the principal surfaces and the external connection terminal of the other one of the principal surfaces is not covered by an insulating member. When the portion of the internal wiring is exposed in the recessed portion, the joining material is joined to the internal wiring exposed in the recessed portion in a state where the joining material has crept up thereon. Thus, the piezoelectric vibration device can be firmly joined to the external substrate.

In another aspect, the piezoelectric vibration device of the present invention preferably has the following configuration. The oscillator and the integrated circuit element are arranged on a same mounting surface of the insulating substrate.

In the configuration described above, the piezoelectric oscillator and the integrated circuit element are arranged on the same mounting surface of the insulating substrate, and therefore, the piezoelectric vibration device can be configured to have a smaller entire height than in a case where the piezoelectric oscillator is arranged on one of the principal surfaces of the insulating substrate and the integrated circuit element is arranged on the other one of the principal surfaces of the insulating substrate. Thus, the piezoelectric vibration device can be firmly joined to the external substrate in a position as close as possible to the external substrate.

### Advantageous Effects of Invention

According to an embodiment of the present invention, even when an impact and a vibration are applied from outside, an external connection terminal is less likely to be separated from an external substrate.

### BRIEF DESCRIPTION OF DRAWINGS

FIG. 1 is a plan view of a piezoelectric vibration device according to a first embodiment of the present invention.

FIG. 2 is an exploded perspective view of an oscillator in the piezoelectric vibration device according to the first embodiment of the present invention.

FIG. 3 is a plan view of the oscillator in the piezoelectric vibration device according to the first embodiment of the present invention.

FIG. 4 is a cross-sectional view in an arrow direction A in FIG. 3.

FIG. 5 is a cross-sectional view in the arrow direction A in FIG. 3 in a state where the piezoelectric vibration device according to the first embodiment of the present invention is resin-molded in a mold.

FIG. 6 is a bottom plan view of the piezoelectric vibration device according to the first embodiment of the present invention.

FIG. 7 is a cross-sectional view in an arrow direction B in FIG. 6.

FIG. 8 is a side view of the piezoelectric vibration device according to the first embodiment of the present invention, illustrating a state where an external connection terminal of the piezoelectric vibration device contacts a solder on a connection terminal of an external substrate.

FIG. 9 is a side view of the piezoelectric vibration device according to the first embodiment of the present invention, illustrating a state where the external connection terminal of the piezoelectric vibration device is joined to the external substrate via the solder on the connection terminal of the external substrate.

FIG. 10 is a cross-sectional view in an arrow direction C in FIG. 9.

FIG. 11 is a side view of an oscillator in a piezoelectric vibration device according to a second embodiment of the present invention.

FIG. 12 is a cross-sectional view in an arrow direction D in FIG. 11.

FIG. 13 is a bottom plan view of the oscillator in the piezoelectric vibration device according to the second embodiment of the present invention.

FIG. 14 is a plan view of the piezoelectric vibration device according to the second embodiment of the present invention.

FIG. 15 is a plan view of a substrate in the piezoelectric vibration device according to the second embodiment of the present invention.

FIG. 16 is a cross-sectional view in an arrow direction E in FIG. 15.

### DESCRIPTION OF EMBODIMENTS

Embodiments will be described hereinafter with reference to the drawings. In the drawings, the same parts are denoted by the same reference numerals, and description thereof will not be repeated. The dimensions of components in the drawings do not strictly represent actual dimensions of the components and dimensional proportions of the components. In the embodiments below, the term “principal surface” refers to a surface having a largest area in a target member or a surface having a largest area when viewed in a thickness direction in a plate member.

In description of a piezoelectric vibration device 1 that is an embodiment of the present invention that will be described below, each of respective longitudinal directions of an oscillator 2 and a substrate 11 is an “X-direction,” each of lateral directions thereof is a “Y-direction, and a direction that is an opening direction of a frame portion 4 in the oscillator 2 and is orthogonal to the X-direction and the Y-direction and a perpendicular direction to a principal surface in the substrate 11 is a “Z-direction.” In this embodiment, the X-direction and the Y-direction are directions in a horizontal plane. The Z-direction is the vertical direction. However, these definitions of the directions are not intended to limit orientations of the piezoelectric vibration device 1 when the piezoelectric vibration device 1 is used.

In the description below, the expression “fixed,” “connected,” “joined,” “attached,” or the like (which will be hereinafter collectively referred to as “fixed or the like”) encompasses not only a case where members are directly fixed or the like to each other, but also a case where members are fixed or the like to each other via some other member. That is, in the description below, the expression “fixed or the like” encompasses a meaning that members are directly and indirectly fixed or the like to each other.

### First Embodiment

### <Configuration of Piezoelectric Vibration Device 1>

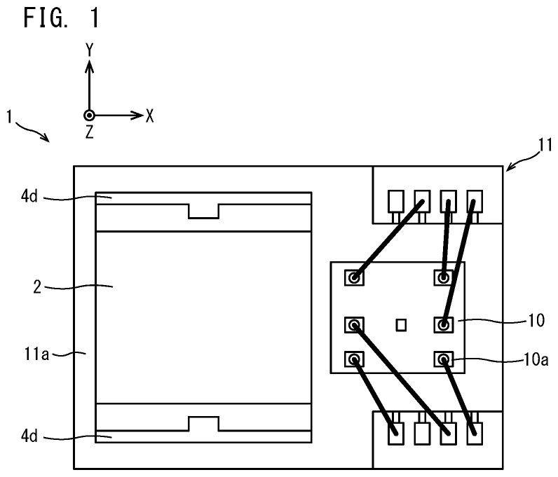

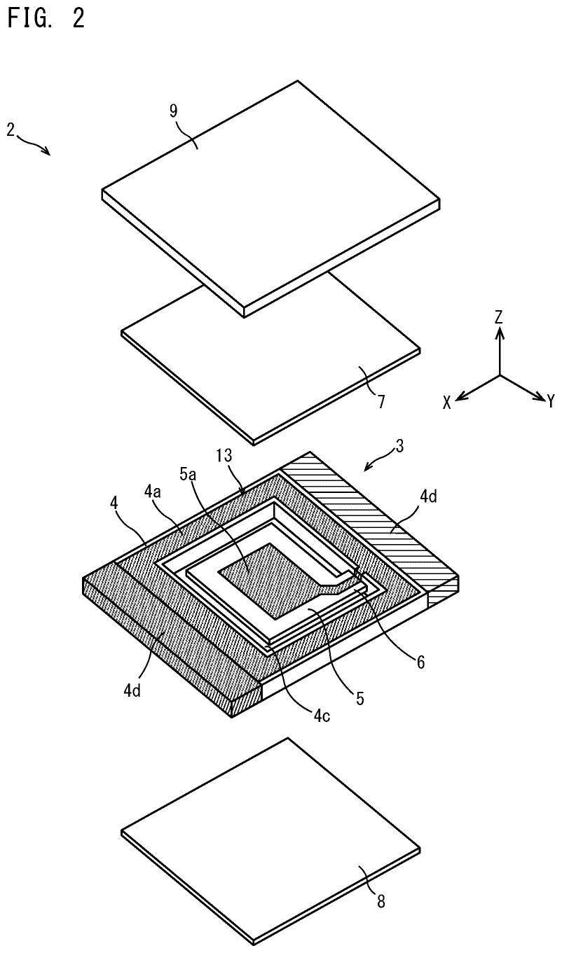

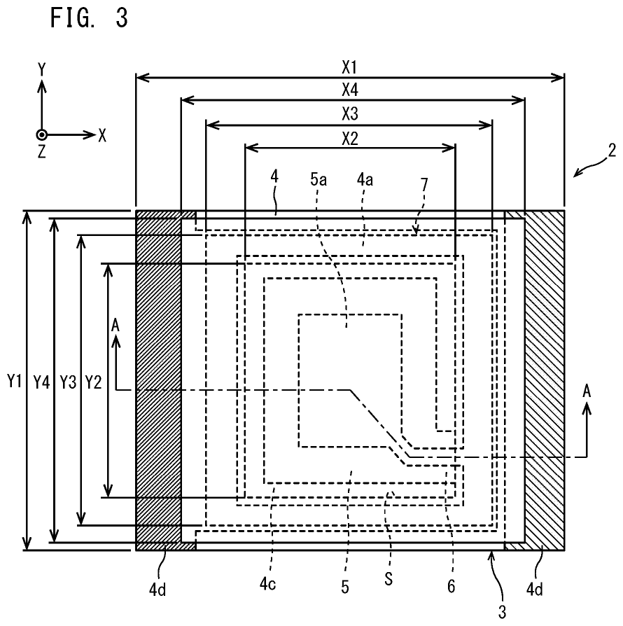

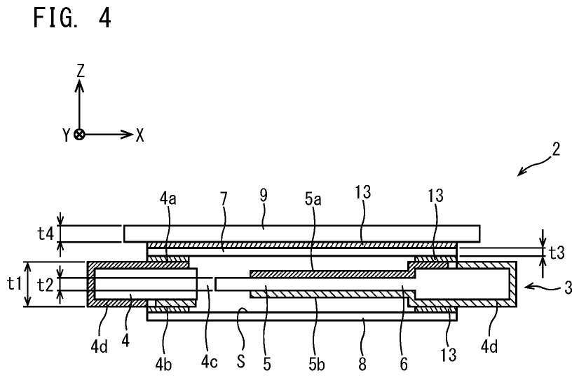

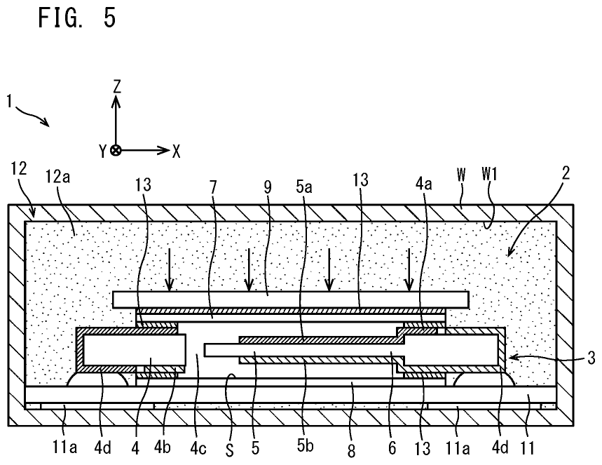

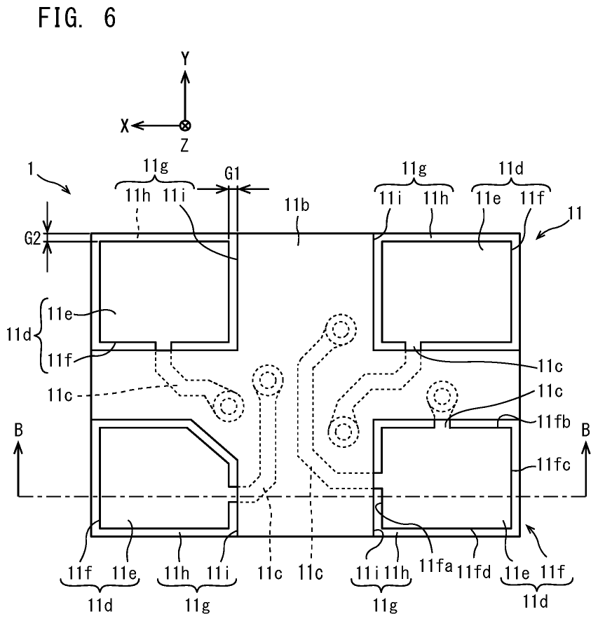

With reference to FIG. 1 to FIG. 5, a piezoelectric vibration device 1 according to the present invention will be described. FIG. 1 is a plan view illustrating an outline of an entire configuration of the piezoelectric vibration device 1. FIG. 2 is an exploded perspective view illustrating an outline of an entire configuration of an oscillator 2 in the piezoelectric vibration device 1. FIG. 3 is a plan view of the oscillator 2. FIG. 4 is a cross-sectional view in an arrow direction A in FIG. 3. FIG. 5 is a cross-sectional view in the arrow direction A in FIG. 3 in a state where the piezoelectric vibration device 1 is resin-molded in a mold W. FIG. 6 is a bottom plan view illustrating an outline of the entire configuration of the piezoelectric vibration device 1.

As illustrated in FIG. 1, the piezoelectric vibration device 1 includes the oscillator 2, an integrated circuit element 10, a substrate 11, and a molding portion 12 (see FIG. 5).

As illustrated in FIG. 2 to FIG. 4, the oscillator 2 is a piezoelectric element with a piezoelectric body that converts an applied force to a voltage or converts an applied voltage to a force. The oscillator 2 includes a piezoelectric vibration plate 3, a first sealing member 7, a second sealing member 8, and a protecting member 9.

The piezoelectric vibration plate 3 is a rectangular crystal vibrating piece that is crystal cut out in a specific direction. The piezoelectric vibration plate 3 includes a frame portion 4, a vibrating portion 5, and a connecting portion 6. In the piezoelectric vibration plate 3, the frame portion 4, the vibrating portion 5, and the connecting portion 6 are molded into one body. That is, the frame portion 4, the vibrating portion 5, and the connecting portion 6 are formed as a single member.

As illustrated in FIG. 3 and FIG. 4, the frame portion 4 surrounds the vibrating portion 5. The frame portion 4 is formed of a plate material having a rectangular shape in a plan view that is a view in a perpendicular direction to a pair of principal surfaces thereof each having a largest area. The frame portion 4 is a frame member that includes the pair of principal surfaces each having a rectangular opening when viewed in the Z-direction, that is, in a plan view. That is, the frame portion 4 includes a rectangular through hole 4c that penetrates from one of the principal surfaces to the other one of the principal surfaces.

A space between the pair of principal surfaces of the frame portion 4, that is, a thickness of the frame portion 4, is a thickness t1. One of the principal surfaces of the frame portion 4 includes a first joined surface 4a joined to the first sealing member 7. The other one of the principal surfaces of the frame portion 4 includes a second joined surface 4b joined to the second sealing member 8. Each of both end portions of the frame portion 4 in the longitudinal direction includes an oscillator mounting terminal 4d.

The vibrating portion 5 is a piezoelectric body. The vibrating portion 5 is a plate material having an approximately rectangular shape in a plan view that is a view in a perpendicular direction to a pair of principal surfaces thereof each having a largest area. The vibrating portion 5 is arranged inside a frame of the frame portion 4. The vibrating portion 5 is arranged such that the pair of principal surfaces are opposed to the openings of the frame portion 4 when viewed in the Z-direction, that is, in a plan view. The principal surfaces of the vibrating portion 5 are arranged approximately in parallel to the principal surfaces of the frame portion 4. A space between the pair of principal surfaces of the vibrating portion 5, that is, a thickness of the vibrating portion 5, is a thickness t2 that is smaller than the thickness t1 of the frame portion 4. The vibrating portion 5 is arranged between the pair of principal surfaces of the frame portion 4 inside the frame of the frame portion 4.

A portion of the vibrating portion 5 is connected to the frame portion 4 via the connecting portion 6 having a plate shape. The vibrating portion 5 is held in a cantilever-supported state on the frame portion 4 via the connecting portion 6. That is, the vibrating portion 5 is surrounded by the frame portion 4 with the through hole 4c interposed therebetween. One of the principal surfaces of the vibrating portion 5 includes a first excitation electrode 5a. The other one of the principal surfaces of the vibrating portion 5 includes a second excitation electrode 5b. The first excitation electrode 5a is connected to one of the oscillator mounting terminals 4d. The second excitation electrode 5b is connected to the other one of the oscillator mounting terminals 4d.

The first sealing member 7 and the second sealing member 8 that are sealing members seal the frame of the frame portion 4. Each of the first sealing member 7 and the second sealing member 8 is a resin film having a rectangular shape in a plan view that is a view in a perpendicular direction to a pair of principal surfaces thereof each having a largest area. Each of the first sealing member 7 and the second sealing member 8 is a polyimide resin film having heat resistance of, for example, approximately 300° C. Each of the first sealing member 7 and the second sealing member 8 has a thickness t3 of about 20 μm to 50 μm.

A width X3 of each of the first sealing member 7 and the second sealing member 8 in the X-direction that is the longitudinal direction is smaller than a width X1 of an outer edge of the frame portion 4 in the X-direction, and is larger than a width X2 of the opening that is an inner edge of the frame portion 4 in the X-direction, when viewed in the Z-direction, that is, in a plan view. When viewed in the Z-direction, a width Y3 of each of the first sealing member 7 and the second sealing member 8 in the Y-direction that is the lateral direction perpendicular to the X-direction is smaller than a width Y1 of the outer edge of the frame portion 4 in the Y-direction and, is larger than a width Y2 of the opening that is the inner edge of the frame portion 4 in the Y-direction. That is, each of the first sealing member 7 and the second sealing member 8 is smaller than the frame portion 4 and is larger than the opening of the frame portion 4.

The first sealing member 7 is joined to the first joined surface 4a of one of the principal surfaces of the frame portion 4 by a joining material 13 that is a thermoplastic adhesive. A peripheral edge of the first sealing member 7 is located more inside than the outer edge of the frame portion 4 and more outside than the inner edge of the frame portion 4. End portions of the first sealing member 7 in the X-direction are joined to the first joined surface 4a of the one of the principal surfaces of the frame portion 4 located in the X-direction. End portions of the first sealing member 7 in the Y-direction are joined to the first joined surface 4a of the one of the principal surfaces of the frame portion 4 located in the Y-direction. That is, when viewed in the Z-direction, a portion of the first sealing member 7 overlapping the first joined surface 4a is joined to the frame portion 4 by the joining material 13. The first sealing member 7 covers the opening of the one of the principal surfaces of the frame portion 4. Thus, the first sealing member 7 closes the opening of the one of the principal surfaces of the frame portion 4.

The second sealing member 8 is joined to the second joined surface 4b of the other one of the principal surfaces of the frame portion 4 by the joining material 13. A peripheral edge of the second sealing member 8 is located more inside than the outer edge of the frame portion 4 and more outside than the inner edge of the frame portion 4. End portions of the second sealing member 8 in the X-direction are joined to the second joined surface 4b of the other one of the principal surfaces of the frame portion 4 located in the X-direction. End portions of the second sealing member 8 in the Y-direction are joined to the second joined surface 4b of the other one of the principal surfaces of the frame portion 4 located in the Y-direction. That is, when viewed in the Z-direction, a portion of the second sealing member 8 overlapping the second joined surface 4b is joined to the frame portion 4 by the joining material 13. The second sealing member 8 covers the opening of the one of the principal surfaces of the frame portion 4. Thus, the second sealing member 8 closes the opening of the other one of the principal surfaces of the frame portion 4.

The protecting member 9 suppresses deflection of at least the first sealing member 7 of the first sealing member 7 and the second sealing member 8 caused by a molding pressure of resin forming the molding portion 12. The protecting member 9 is a plate member having a rectangular shape in a plan view that is a view in a perpendicular direction to a pair of principal surfaces thereof each having a largest area. The protecting member 9 is formed of silicon that is a brittle material. It is desirable that the protecting member 9 has a rigidity that allows a maximum amount of deflection to be 20 μm or less in a state of being held at both ends in the longitudinal direction under application of a pressure generated during molding using resin.

Therefore, for the protecting member 9, a modulus of longitudinal elasticity of a material and a cross-sectional secondary moment in the Z-direction that is a direction of a plan view are set such that the protecting member 9 has a higher rigidity than that of at least the first sealing member 7 of the first sealing member 7 and the second sealing member 8. In this embodiment, the protecting member 9 is silicon. In this embodiment, it is desirable that the protecting member 9 has a thickness t4 of about 30 μm to 100 μm. The thickness t4 of the protecting member 9 is larger than the thickness t3 of each of the first sealing member 7 and the second sealing member 8.

A width X4 of the protecting member 9 in the X-direction that is the longitudinal direction is smaller than the width X1 of the outer edge of the frame portion 4 of the piezoelectric vibration plate 3 in the X-direction and is larger than the width X3 of the first sealing member 7 in the X-direction, when viewed in the Z-direction. A width Y4 of the protecting member 9 in the Y-direction that is a perpendicular direction to the X-direction is smaller than the width Y1 of the outer edge of the frame portion 4 in the Y-direction and is larger than the width Y3 of the first sealing member 7 in the Y-direction, when viewed in the Z-direction. That is, the protecting member 9 is smaller than the frame portion 4 and is larger than the first sealing member 7.

The protecting member 9 is joined to a surface of the first sealing member 7 extending perpendicular to the Z-direction by a thermoplastic additive or a die attach agent, that is, the joining material 13. A peripheral edge of the protecting member 9 is located between the peripheral edge of the first sealing member 7 and the outer edge of the frame portion 4. That is, a peripheral edge portion of the protecting member 9 overlaps the first joined surface 4a of the frame portion 4, when viewed in the Z-direction. Thus, the protecting member 9 is supported by the frame portion 4 at the peripheral edge portion thereof. The protecting member 9 covers the opening of the one of the principal surfaces of the frame portion 4 via the first sealing member 7. That is, the protecting member 9 covers the entire first sealing member 7 including a portion overlapping the opening when viewed in the Z-direction.

The oscillator 2 configured in the above-described manner has a three-layer structure including the piezoelectric vibration plate 3, the first sealing member 7 that closes the opening of the one of the principal surfaces of the piezoelectric vibration plate 3, and the second sealing member 8 that closes the opening of the other one of the principal surfaces of the piezoelectric vibration plate 3. The oscillator 2 has an internal space S formed by the frame portion 4 of the piezoelectric vibration plate 3, the first sealing member 7, and the second sealing member 8. The oscillator 2 includes the vibrating portion 5 arranged in the internal space S. An inert gas, such as nitrogen gas, is enclosed in the internal space S. The oscillator 2 oscillates at a predetermined frequency by a voltage applied from each of the oscillator mounting terminals 4d.

As illustrated in FIG. 1, the integrated circuit element 10 is an IC that controls the oscillator 2. The integrated circuit element 10 includes an electronic circuit, such as an oscillation circuit that is connected to a thermosensitive element (thermistor) that detects a surrounding temperature state and generates a predetermined oscillation output, or the like. The integrated circuit element 10 outputs the oscillation output generated by the oscillation circuit as a reference signal, such as a clock signal, to outside via integrated circuit element mounting terminals 10a. A portion of the integrated circuit element 10 except the integrated circuit element mounting terminals 10a is covered by resin.

As illustrated in FIG. 1, the substrate 11 is an insulating substrate that electrically connects the oscillator 2 and the integrated circuit element 10 to each other with a wiring pattern (not illustrated) and forms the oscillator 2 and the integrated circuit element 10 as an integrated body. The substrate 11 is formed of a resin material. The substrate 11 includes, as a base material, for example, glass epoxy resin that is an insulator that can be easily processed by cutting or the like. Using the substrate 11, the piezoelectric vibration device 1 having an arbitrary shape can be easily configured. The substrate 11 is a rectangular plate material. In this embodiment, the substrate 11 has a thickness of, for example, 0.17 mm. One of principal surfaces of the substrate 11 is formed as a first mounting surface 11a including the wiring pattern that includes a pad, a land, or the like formed of a conductor, such as copper.

The oscillator 2 and the integrated circuit element 10 are each mounted on the first mounting surface 11a of the substrate 11. Each of both the oscillator mounting terminals 4d of the oscillator 2 is electrically connected to the wiring pattern of the first mounting surface 11a by the conductive joining material 13. At this time, the oscillator 2 is arranged such that the principal surfaces thereof covered by the first sealing member 7 and the second sealing member 8 face in the Z direction. The oscillator 2 is arranged such that the second sealing member 8 is opposed to the first mounting surface 11a. The second sealing member 8 contacts the first mounting surface 11a. Similarly, each integrated circuit element mounting terminal 10a of the integrated circuit element 10 is electrically connected to the wiring pattern of the first mounting surface 11a of the substrate 11 by the conductive joining material 13. In a manner described above, the oscillator 2 and the integrated circuit element 10 are arranged side by side on the first mounting surface 11a of the substrate 11.

Aa illustrated in FIG. 6, the other one of the principal surface of the substrate 11 that is in parallel to the one of the principal surfaces is configured as a second mounting surface 11b including external connection terminals 11d provided for mounting the substrate 11 on an external substrate P. The external connection terminals 11d each are a plate-shaped terminal formed of conductive metal. The wiring pattern of the first mounting surface 11a is electrically connected to the external connection terminals 11d via internal wirings 11c.

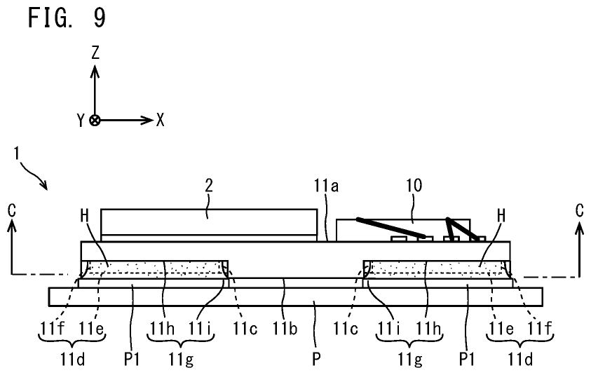

The oscillator 2 mounted on the substrate 11 is electrically connected to the external substrate P from the oscillator mounting terminal 4d via the unillustrated wiring pattern on the first mounting surface 11a, the internal wiring 11c, and the external connection terminal 11d of the second mounting surface 11b (see FIG. 9). The vibrating portion 5 of the oscillator 2 is held in a cantilever-supported state on the frame portion 4 of the piezoelectric vibration plate 3 by the connecting portion 6. Thus, the vibrating portion 5 oscillates at a predetermined frequency by a voltage applied from the external substrate P.

As illustrated in FIG. 5, the molding portion 12 protects the substrate 11 and at least the oscillator 2 of the oscillator 2 and the integrated circuit element 10 mounted on the substrate 11 (see FIG. 6). The molding portion 12 is thermosetting resin, such as epoxy resin 12a. The molding portion 12 covers the substrate 11 and at least a portion of the oscillator 2 of the oscillator 2 and the integrated circuit element 10 mounted on the substrate 11 with the epoxy resin 12a cured by heat. In this embodiment, the molding portion 12 covers the substrate 11, and the oscillator 2 and the integrated circuit element 10 mounted on the substrate 11.

As the oscillator 2 of the piezoelectric vibration device 1 configured as described above, the oscillator 2 having a three-layer structure, in which the piezoelectric vibration plate 3 that supports the vibrating portion 5 having a smaller thickness than that of the frame portion 4 inside the frame of the frame portion 4 is covered by the first sealing member 7 and the second sealing member 8 that are resin films, is provided. Therefore, the piezoelectric vibration device 1 can be configured such that an entire height thereof is reduced, as compared to a piezoelectric vibration device including an oscillator configured such that a vibrating portion held by a box-shaped holding member is sealed by a lid member. The protecting member 9 covers the first sealing member 7 with the peripheral edge thereof supported by the frame portion 4. The oscillator 2 is configured such that the first sealing member 7 is covered by the protecting member 9, so that resistance of the first sealing member 7 to the molding pressure from the mold resin is increased.

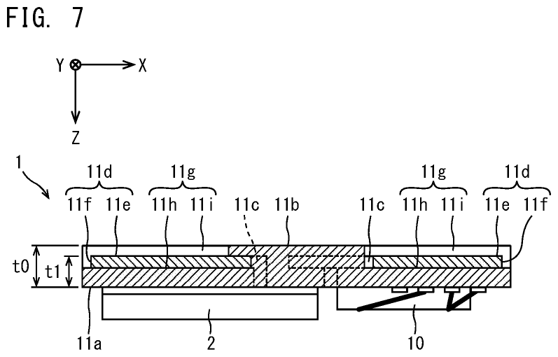

Next, with reference to FIG. 6 and FIG. 7, the second mounting surface 11b and the external connection terminal 11d of the substrate 11 will be described in detail. FIG. 7 is a cross-sectional view in an arrow direction B in FIG. 6. In this embodiment, the second mounting surface 11b includes four external connection terminals 11d.

As illustrated in FIG. 6 and FIG. 7, the second mounting surface 11b of the substrate 11 is the other one of the principal surfaces of the substrate 11 that is electrically connected to the external substrate P. The second mounting surface 11b includes four recessed portions 11g corresponding to the four external connection terminals 11d. Each of the four recessed portions 11g is a stepped portion in which a portion in an arbitrarily defined range is recessed in a perpendicular direction to the second mounting surface 11b. Each of the four recessed portions 11g includes a bottom surface 11h extending in parallel to the second mounting surface 11b and side surfaces 11i extending perpendicular to the second mounting surface 11b. Each of the four recessed portions 11g is arranged at a corresponding one of four corners each including a vertex that is an intersection between a long side and a short side of the substrate 11 when viewed in the Z-direction. As for each of the four recessed portions 11g, a range including respective portions of the long side and the short side each extending from the vertex and being an outer edge of the substrate 11 is recessed. In this embodiment, three of the four recessed portions 11g each have a rectangular shape when viewed in the Z-direction. The other one of the four recessed portions 11g has a pentagonal shape.

Each of the external connection terminals 11d is configured as a terminal via which the one of the principal surfaces is joined to a connection terminal P1 of the external substrate P. Each of the four external connection terminals 11d is arranged in a corresponding one of the four recessed portions 11g. The external connection terminal 11d includes a joined surface 11e connected to the connection terminal P1 on the principal surface when viewed in the Z-direction. The joined surface 11e is not covered by the insulating base material of the substrate 11 and is exposed. The joined surface 11e extends in parallel to the second mounting surface 11b.

As illustrated in FIG. 6, the external connection terminal 11d has a shape smaller than the bottom surface 11h when viewed in the Z-direction. Therefore, the external connection terminal 11d is included in the bottom surface 11h when viewed in the Z-direction. Furthermore, the external connection terminal 11d is arranged in the recessed portion 11g with a predetermined space from an outer edge of the bottom surface 11h. That is, the end surface 11f including four end surfaces 11fa, 11fb, 11fc, and 11fd including the outer edge of the external connection terminal 11d is arranged more inside than the outer edge of the bottom surface 11h in the recessed portion 11g so as to be separated from the outer edge of the bottom surface 11h with a predetermined gap G therebetween, when viewed in the Z-direction.

Each of the end surface 11fa adjacent to one of the side surfaces 11i and the end surface 11fb adjacent to another one of the side surfaces 11i in the recessed portion 11g is located with a gap G1 from a corresponding one of the side surfaces 11i, when viewed in the Z-direction. The end surface 11fc adjacent to one of the short sides of the substrate 11 and the end surface 11fd adjacent to one of the long sides of the substrate 11 in the recessed portion 11g are located such that a predetermined gap G2 is provided between the end surface 11fd and the long side and between the end surface 11fc and the short side, when viewed in the Z-direction. As described above, the external connection terminal 11d is configured such that the four end surfaces 11fa, 11fb, 11fc, and 11fd forming the outer edge are exposed. The bottom surface 11h of the recessed portion 11g is exposed around the external connection terminal 11d. A trench is formed around the external connection terminal 11d by the side surfaces 11i of the recessed portion 11g, the bottom surface 11h of the recessed portion 11g, and the end surface 11f of the external connection terminal 11d.

The internal wiring 11c is connected to the external connection terminal 11d. The internal wiring 11c is formed of conductive metal. The internal wiring 11c electrically connects the wiring pattern of the first mounting surface 11a and the external connection terminal 11d to each other. The internal wiring 11c extends in the substrate 11 to be located in the recessed portion 11g. The internal wiring 11c is connected to at least one of the four end surfaces 11fa, 11fb, 11fc, and 11fd of the external connection terminal 11d in the recessed portion 11g. The internal wiring 11c protrudes from the end surface 11f to which the internal wiring 11c is connected toward a corresponding one of the side surfaces 11i of the recessed portion 11g, when viewed in the Z-direction. The internal wiring 11c does not protrude beyond the joined surface 11e of the external connection terminal 11d. The internal wiring 11c is not covered by the base material of the substrate 11 in the recessed portion 11g. That is, similar to the external connection terminal 11d, the internal wiring 11c is not covered by the insulating base material of the substrate 11 and is exposed.

A thickness t1 from the first mounting surface 11a of the substrate 11 to the joined surface 11e of the external connection terminal 11d is less than a thickness to of the substrate 11 that is a thickness from the first mounting surface 11a to the second mounting surface 11b. That is, the joined surface 11e of the external connection terminal 11d does not protrude beyond the second mounting surface 11b of the substrate 11. Thus, a recess amount of the recessed portion 11g is larger than a thickness of the external connection terminal 11d.

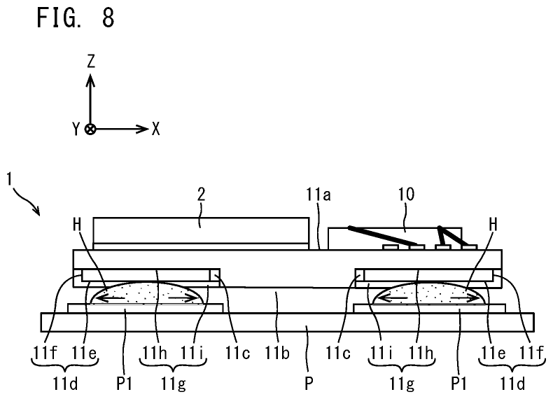

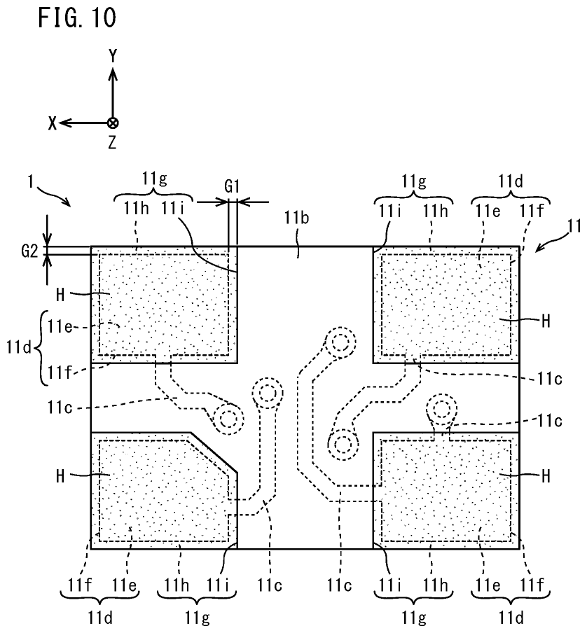

Next, with reference to FIG. 8 to FIG. 10, a method in which the substrate 11 is joined to the external substrate P will be described. FIG. 8 is a side view of the piezoelectric vibration device 1, illustrating a state where the external connection terminal 11d of the piezoelectric vibration device 1 contacts a solder H on the connection terminal P1 of the external substrate P. FIG. 9 is a side view of the piezoelectric vibration device 1, illustrating a state where the external connection terminal 11d of the piezoelectric vibration device 1 is joined to the external substrate P by the solder H on the connection terminal P1 of the external substrate P. FIG. 10 is a cross-sectional view in an arrow direction C in FIG. 9.

As illustrated in FIG. 8, the external connection terminal 11d is joined to the connection terminal of the external substrate P by the solder. Each of the four external connection terminals 11d of the substrate 11 is joined to a corresponding one of the connection terminals P1 in the external substrate P by the applied solder. The solder His joined to the connection terminal P1 and is also joined to the external connection terminal 11d, thereby joining the external substrate P and the substrate 11 to each other. By making the substrate 11 closer to the external substrate P, the solder H on the external substrate P is attached to the joined surface 11e of the external connection terminal 11d. The solder H spreads toward the outer edge of the external connection terminal 11d as the substrate 11 is pressed against the external substrate P.

As illustrated in FIG. 9 and FIG. 10, when the solder H reaches the outer edge of the external connection terminal 11d, the solder H enters the gap G1 between the side surfaces 11i of the recessed portion 11g and the end surfaces 11fa and 11fb of the external connection terminal 11d from the joined surface 11e (see FIG. 6). The solder H covers the joined surface 11e and the four end surfaces 11f in the external connection terminal 11d and the internal wiring 11c exposed at the bottom surface 11h in the recessed portion 11g of the substrate 11. The solder H is joined to the joined surface 11e and the four end surfaces 11f in the external connection terminal 11d and also is joined to the internal wiring 11c exposed at the bottom surface 11h in the recessed portion 11g of the substrate 11. Note that the solder H is joined to the joined surface 11e, the four end surfaces 11f, and the internal wiring 11c in a state where the solder H physically contacts the side surfaces 11i of the recessed portion 11g in some cases.

The solder H of the external substrate P attached to the joined surface 11e of the external connection terminal 11d spreads toward the internal wiring 11c connected to at least one of the four end surfaces 11fa, 11fb, 11fc, and 11fd. The solder H covers the internal wiring 11c in the external connection terminal 11d. The solder H is joined to the internal wiring 11c in the external connection terminal 11d in a state where the solder H has crept up thereon.

The piezoelectric vibration device 1 configured in a manner described above includes a piezoelectric oscillator having a three-layer structure in which the principal surfaces of the piezoelectric vibration plate 3 are sealed by the first sealing member 7 and the second sealing member 8 that are resin films. Therefore, the piezoelectric vibration device 1 can be configured to have a smaller entire height, as compared to a configuration including a piezoelectric oscillator configured such that a box-shaped holding member formed of ceramic or the like is sealed by a lid member.

The piezoelectric vibration device 1 is configured such that the oscillator 2 and the integrated circuit element 10 are mounted on the same first mounting surface 11a of the substrate 11. Therefore, the piezoelectric vibration device 1 can be configured to have a smaller entire height, as compared to a configuration in which the oscillator 2 is mounted on the first mounting surface 11a of the substrate 11 and the integrated circuit element 10 is mounted on the second mounting surface 11b of the substrate 11.

The external connection terminal 11d in the recessed portion 11g is arranged in a position closer to the first mounting surface 11a than to the second mounting surface 11b. Therefore, in the piezoelectric vibration device 1, the external connection terminal 11d is joined to the external substrate P in a position closer to the external substrate P than in a case where the external connection terminal 11d is not arranged in the recessed portion 11g. That is, the external substrate P to which the piezoelectric vibration device 1 is joined can be configured to have a smaller entire height than in a case where the external connection terminal 11d of the piezoelectric vibration device 1 is arranged on the second mounting surface 11b.

The piezoelectric vibration device 1 includes the molding portion 12 in which at least one of the oscillator 2 or the integrated circuit element 10 is covered with resin together with the substrate 11, and therefore, at least one of the oscillator 2 or the integrated circuit element 10 can be protected from an impact and a vibration from outside. Moreover, the rigidity of the substrate 11 is increased because of the molding portion 12, so that the external connection terminals 11d are less likely to be deflected due to an impact and a vibration. Therefore, in the piezoelectric vibration device 1, a distortion generated in the joined surfaces 11e between the external connection terminals 11d and the solder H due to an impact and a vibration from outside can be suppressed.

The solder H is joined to the internal wiring 11c, the joined surface 11e, and the four end surfaces 11f, and therefore, the external connection terminal 11d has an increased area of a joined portion joined with the solder, as compared to a case where only the joined surface 11e is joined with the solder H. Therefore, a joining force between the substrate 11 and the external substrate P is increased, as compared to a case where only the joined surface 11e is joined to the connection terminal P1 of the external substrate P by the solder H. Thus, the piezoelectric vibration device 1 can be firmly joined to the external substrate P in a position as close as possible to the external substrate P.

### Second Embodiment

### <Configuration of Piezoelectric Vibration Device 21>

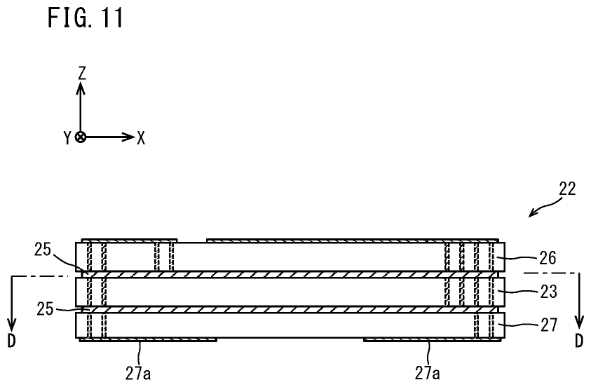

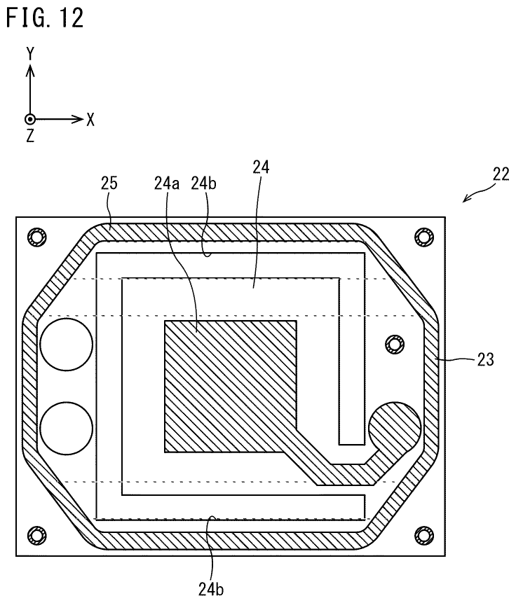

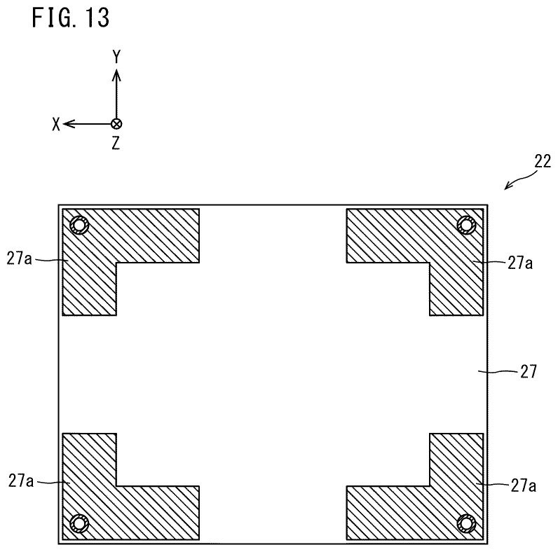

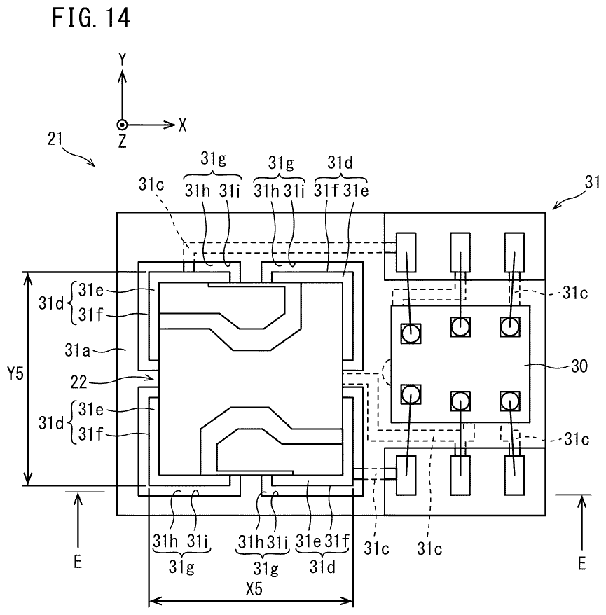

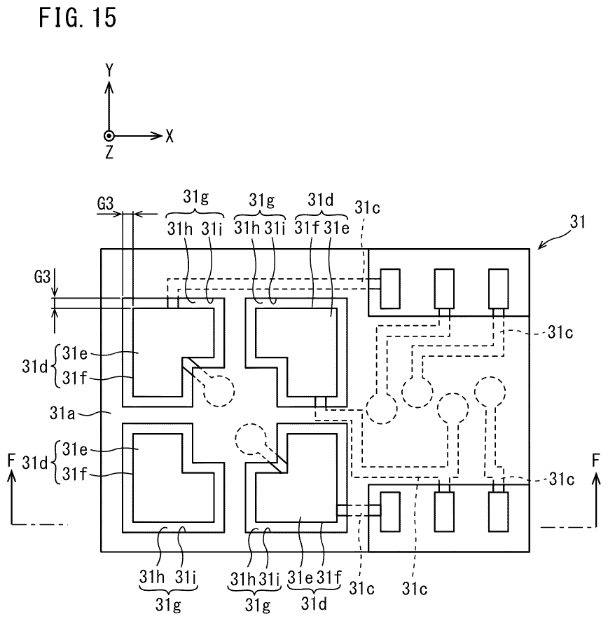

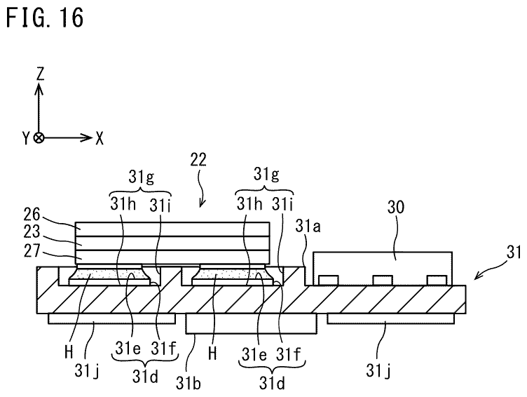

Next, with reference to FIG. 11 to FIG. 16, a piezoelectric vibration device 21 that is a second embodiment of a piezoelectric vibration device according to the present invention will be described. FIG. 11 is a side view of an oscillator 22 in the piezoelectric vibration device 21 according to the second embodiment of the present invention. FIG. 12 is a cross-sectional view in an arrow direction D in FIG. 11. FIG. 13 is a bottom plan view of the oscillator 22 in the piezoelectric vibration device 21. FIG. 14 is a plan view of the piezoelectric vibration device 21. FIG. 15 is a plan view of a substrate 31 in the piezoelectric vibration device 21. FIG. 16 is a cross-sectional view in an arrow direction E in FIG. 15. Note that, in the following embodiment, specific description of similar points to those in the embodiment already described will be omitted and only a portion which differs from the already described embodiment will be described in detail.

As illustrated in FIG. 14, the piezoelectric vibration device 21 includes the oscillator 22, an integrated circuit element 30, the substrate 31, and a molding portion (not illustrated).

As illustrated in FIG. 11 to FIG. 13, the oscillator 22 is a piezoelectric oscillator including a piezoelectric vibration plate 23, a first sealing member 26, and a second sealing member 27. The oscillator 22 has a sandwich structure in which the piezoelectric vibration plate 23 is sandwiched between the first sealing member 26 and the second sealing member 27.

As illustrated in FIG. 12, the piezoelectric vibration plate 23 is a plate member formed of crystal that is a piezoelectric material. Each of one and the other one of principal surfaces of the piezoelectric vibration plate 23 includes a corresponding one of a pair of excitation electrodes 24a. The pair of the excitation electrodes 24a are arranged to be opposed to each other in a thickness direction of the piezoelectric vibration plate 23. The piezoelectric vibration plate 23 includes a notch portion 24b that penetrates from one of the principal surfaces to the other one of the principal surfaces such that the notch portion 24b surrounds the pair of excitation electrodes 24a when viewed in the Z-direction that is a plan view. The notch portion 24b passes through the piezoelectric vibration plate 23 to surround the pair of excitation electrodes 24a with portions of the excitation electrodes 24a left non-surrounded. Thus, a portion in which the pair of excitation electrodes 24a are arranged is configured as a plate member having a cantilever structure. That is, the portion in which the pair of excitation electrodes 24a are arranged is configured as a vibrating portion 24 that can vibrate in the Z-direction.

The piezoelectric vibration plate 23 includes a joining material 25 connected to the first sealing member 26 such that the joining material 25 surrounds the vibrating portion 24 on one of the principal surfaces thereof. Similarly, the piezoelectric vibration plate 23 incudes a joining material 25 connected to the second sealing member such that the joining material 25 surrounds the vibrating portion 24 on the other one of the principal surfaces thereof. Each of the joining materials 25 is a PVD film formed of the same metal as metal that forms the pair of excitation electrodes 24a.

The first sealing member 26 seals the vibrating portion 24 of the piezoelectric vibration plate 23. The first sealing member 26 is a plate member formed of the same crystal as the piezoelectric vibration plate 23. The first sealing member 26 has approximately the same shape as the piezoelectric vibration plate 23. That is, the first sealing member 26 has a shape that can entirely cover one of the principal surfaces of the piezoelectric vibration plate 23 with one of principal surfaces of the first sealing member 26 when the one of the principal surfaces of the first sealing member 26 is arranged to be opposed to the one of the principal surfaces of the piezoelectric vibration plate 23. The first sealing member 26 includes the joining material 25 that is joined to the joining material 25 of the piezoelectric vibration plate 23 on the one of the principal surfaces thereof. The joining material 25 of the first sealing member 26 is a PVD film formed of the same metal as metal forming the joining material 25 of the piezoelectric vibration plate 23.

As illustrated in FIG. 11, the second sealing member 27 seals the vibrating portion 24 of the piezoelectric vibration plate 23. The second sealing member 27 is a plate member formed of the same crystal as the piezoelectric vibration plate 23. The second sealing member 27 has approximately the same shape as the piezoelectric vibration plate 23. That is, the second sealing member 27 has a shape that can entirely cover the other one of the principal surfaces of the piezoelectric vibration plate 23 with one of principal surfaces of the second sealing member 27 when the one of the principal surfaces of the second sealing member 27 is arranged to be opposed to the other one of the principal surfaces of the piezoelectric vibration plate 23. The second sealing member 27 includes a joining material 25 that is joined to the joining material 25 of the piezoelectric vibration plate 23 on the one of the principal surfaces thereof. The joining material 25 is a PVD film formed of the same metal as the metal that forms the joining material 25.

The second sealing member 27 includes, on the other one of the principal surfaces thereof, four oscillator mounting terminals 27a each being electrically connected to an electrode of the substrate 31. Each of the four oscillator mounting terminals 27a is a plate-shaped terminal formed of conductive metal. Each of the four oscillator mounting terminals 27a is formed into an approximately L-shape when viewed in the Z-direction.

The first sealing member 26 is arranged on one of the principal surfaces of the piezoelectric vibration plate 23. The one of the principal surfaces of the piezoelectric vibration plate 23 is covered by the first sealing member 26. At this time, the joining material 25 of the one of the principal surfaces of the piezoelectric vibration plate 23 and the joining material 25 of the first sealing member 26 are diffusion-bonded. Thus, the excitation electrode 24a at the one of the principal surfaces of the piezoelectric vibration plate 23 is hermetically sealed with the first sealing member 26.

The second sealing member 27 is arranged on the other one of the principal surfaces of the piezoelectric vibration plate 23. The other one of the principal surfaces of the piezoelectric vibration plate 23 is covered by the second sealing member 27. At this time, the joining material 25 of the other one of the principal surfaces of the piezoelectric vibration plate 23 and the joining material 25 of the second sealing member 27 are diffusion-bonded. Thus, the excitation electrode 24a at the other one of the principal surfaces of the piezoelectric vibration plate 23 is hermetically sealed with the second sealing member 27.

The oscillator 22 configured in a manner described above is configured as a package having a sandwich structure in which each of the principal surfaces of the piezoelectric vibration plate 23 is sealed with a corresponding one of the first sealing member 26 and the second sealing member 27. The oscillator 22 is configured such that each of both the principal surfaces of the piezoelectric vibration plate 23 is covered by a corresponding one of the first sealing member 26 and the second sealing member 27, and thus, an internal space that includes the vibrating portion 24 of the piezoelectric vibration plate 23 therein is formed. That is, the oscillator 22 is configured such that the vibrating portion 24 including the pair of excitation electrodes 24a is hermetically sealed in the internal space of the package.

As illustrated in FIG. 14, the integrated circuit element 30 is an IC that controls the oscillator 22. A configuration of the integrated circuit element 30 is the same as the configuration of the integrated circuit element 10 of the first embodiment, and therefore, description thereof will be omitted.

The substrate 31 electrically connects the oscillator 22 and the integrated circuit element 30 to each other with a wiring pattern and forms the oscillator 22 and the integrated circuit element 30 as an integrated body. One of principal surfaces of the substrate 31 is formed as a first mounting surface 31a including four connection terminals 31d and the wiring pattern that are formed of a conductor such as copper, where the wiring pattern includes a pad, a land, or the like. The four connection terminals 31d are electrically connected to the wiring pattern of the first mounting surface 31a including a plurality of pads via internal wirings 31c.

The oscillator 22 and the integrated circuit element 30 are each mounted on the first mounting surface 31a of the substrate 31. The oscillator 22 is arranged on the substrate 31 such that the second sealing member 27 is opposed to the first mounting surface 31a (see FIG. 16). Each of the four oscillator mounting terminals 27a of the second sealing member 27 (see FIG. 13) is electrically connected to a corresponding one of the four connection terminals 31d of the first mounting surface 31a by the conductive solder H (see FIG. 16). Similarly, each of integrated circuit element mounting terminals 30a of the integrated circuit element 30 is electrically connected to the wiring pattern of the first mounting surface 31a of the substrate 31 by the conducive solder H. In a manner described above, the oscillator 22 and the integrated circuit element 30 are arranged side by side on the first mounting surface 31a of the substrate 31.

As illustrated in FIG. 16, the other one of the principal surface of the substrate 31 that extends in parallel to the one of the principal surfaces is configured as a second mounting surface 31b that includes external connection terminals 31j provided for mounting the substrate 31 on an external substrate P (see FIG. 9). The external connection terminals 31j each are a plate-shaped terminal formed of conductive metal. The external connection terminal 31j is electrically connected to the wiring pattern of the first mounting surface 31a including a plurality of pads via the internal wiring 31c (not illustrated).

The unillustrated molding portion protects the substrate 31 and at least the oscillator 22 of the oscillator 22 and the integrated circuit element 30 mounted on the substrate 31. The molding portion is similar to the molding portion 12 in the first embodiment, and therefore, description thereof will be omitted.

Next, with reference to FIG. 14 to FIG. 16, the first mounting surface 31a and the connection terminals 31d of the substrate 31 will be described in detail. The second mounting surface 31b of the substrate 31 is identical to the second mounting surface 11b of the substrate 11 in the first embodiment, and therefore, description thereof will be omitted.

As illustrated in FIG. 14 to FIG. 16, the first mounting surface 31a of the substrate 31 is one of principal surfaces thereof electrically connected to the oscillator 22 and the integrated circuit element 30. The first mounting surface 31a includes four recessed portions 31g (which will be hereinafter referred to merely as the “recessed portions 31g”). The recessed portions 31g are arranged linearly symmetric with each other in the X-direction and the Y-direction, when viewed in the Z-direction. In each of the recessed portions 31g, an approximately L-shaped range is recessed in a perpendicular direction to the first mounting surface 31a. Each of the recessed portions 31g includes a bottom surface 31h extending in parallel to the first mounting surface 31a and side surfaces 31i extending perpendicular to the first mounting surface 31a. Each of the recessed portions 31g has a shape with which a corresponding one of the oscillator mounting terminals 27a of the oscillator 22 with one of the principal surfaces thereof facing to the bottom surface 31h can be arranged in the recessed portion 31g. In each of the recessed portions 31g, a corresponding one of the connection terminals 31d having an approximately L shape is arranged. That is, the substrate 31 includes the four connection terminals 31d. Each of the connection terminals 31d is a plate-shaped terminal formed of conductive metal.

As illustrated in FIG. 16, each of the connection terminals 31d protrudes from the bottom surface 31h of a corresponding one of the recessed portions 31g in the Z-direction. A principal surface of each of the four connection terminals 31d (which will be hereinafter referred to merely as the “connection terminals 31d”) extending perpendicular to the Z-direction is configured as a joined surface 31e connected to a corresponding one of the four oscillator mounting terminals 27a of the oscillator 22. Each of the connection terminals 31d is arranged in a corresponding one of the recessed portions 31g such that a predetermined gap G3 from the side surface 31i of the bottom surface 31h is generated. The joined surface 31e is not covered by an insulating base material of the substrate 31 and is exposed. The joined surface 31e of the connection terminal 31d is located in a position closer to the bottom surface 31h than to the first mounting surface 31a. That is, the joined surface 31e is recessed to a lower level than the first mounting surface 31a.

As illustrated in FIG. 14, each of the connection terminals 31d is configured such that end surfaces 31f extending perpendicular to the bottom surface 31h of the recessed portion 31g are at an outer edge. A width X5 in the X-direction of the two connection terminals 31d arranged side by side in the X-direction is larger than a width of the oscillator 22 in the X-direction. A width Y5 in the Y-direction of the two connection terminals 31d arranged side by side in the Y-direction is larger than a width of the oscillator 22 in the Y-direction. That is, each of the connection terminals 31d extends more outside than the outer edge of the oscillator 22 in the X-direction and the Y-direction, when viewed in the Z-direction.

To each of the connection terminals 31d, a corresponding one of the internal wirings 31c is connected. Each of the internal wirings 31c is formed of conductive metal. The internal wiring 31c electrically connects the wiring pattern of the first mounting surface 31a and a corresponding one of the external connection terminals 31j. The internal wiring 31c is connected to a corresponding one of the connection terminals 31d in a corresponding one of the recessed portions 31g. The internal wiring 31c does not protrude beyond the joined surface 31e of the connection terminal 31d. The internal wiring 31c is not covered by the base material of the substrate 31 in the recessed portion 31g. That is, similar to the connection terminal 31d, the internal wiring 31c is not covered by the insulating base material of the substrate 31 and is exposed.

Next, with reference to FIG. 14 and FIG. 16, joining of the oscillator 22 and the substrate 31 will be described.

As illustrated in FIG. 14, the oscillator 22 is arranged on the first mounting surface 31a in a state where the other one of the principal surfaces of the second sealing member 27 faces the bottom surfaces 31h of the recessed portions 31g. The side surfaces 31i of the recessed portions 31g are located around the outer edge of the oscillator 22. When viewed in the Z-direction, a portion of each of the connection terminals 31d is located between the outer edge of the oscillator 22 and a corresponding one of the side surfaces 31i.

As illustrated in FIG. 14 and FIG. 16, each of the four oscillator mounting terminals 27a of the oscillator 22 is joined to a corresponding one of the four connection terminals 31d of the substrate 31 by the solder H applied to the connection terminal 31d. The solder H each adheres to the oscillator mounting terminal 27a and the connection terminal 31d. The solder H located between the oscillator mounting terminal 27a and the connection terminal 31d spreads toward an outer edge of the connection terminal 31d as the oscillator 22 and the substrate 31 become closer to each other.

When the solder H each reaches the outer edge of the corresponding connection terminal 31d, the solder H each spreads toward the corresponding end surfaces 31f from the corresponding joined surface 31e. The solder H each covers the joined surface 11e and the end surfaces 31f in the corresponding connection terminal 31d. That is, the solder H each joins the oscillator mounting terminal 27a of the oscillator 22 to the joined surface 31e and the end surfaces 31f.

The solder H adhering to the joined surface 31e of the connection terminal 31d spreads toward the internal wiring 31c connected to the connection terminal 31d. The solder H covers the internal wiring 31c in the connection terminal 31d. The solder H joins the oscillator mounting terminals 27a and the connection terminals 31d to each other in a state where the solder H covers the internal wiring 31c in each of the connection terminals 31d.

The oscillator 22 mounted on the substrate 31 is electrically connected to an unillustrated external substrate from the four oscillator mounting terminals 27a via the four connection terminals 31d on the first mounting surface 31a, an unillustrated wiring pattern including a plurality of pads, the internal wirings 31c, and the external connection terminals 31j extending on the second mounting surface 31b. Thus, the vibrating portion 5 of the oscillator 22 oscillates at a predetermined frequency by a voltage applied from the external substrate.

The piezoelectric vibration device 21 configured in a manner described above includes the oscillator 22 having a sandwich structure in which each of the principal surfaces of the piezoelectric vibration plate 23 is sealed with a corresponding one of the first sealing member 26 and the second sealing member 27 that are crystal plate materials. Therefore, the piezoelectric vibration device 21 can be configured to have a smaller entire height, as compared to a configuration including a piezoelectric oscillator configured such that a box-shaped holding member formed of ceramic or the like is sealed by a lid member.

The piezoelectric vibration device 21 is configured such that the oscillator 22 and the integrated circuit element 30 are mounted on the same first mounting surface 31a of the substrate 31. Therefore, the piezoelectric vibration device 21 can be configured to have a smaller entire height, as compared to a configuration in which the oscillator 22 is mounted on the first mounting surface 31a of the substrate 31 and the integrated circuit element 30 is mounted on the second mounting surface 31b.

The piezoelectric vibration device 21 includes an unillustrated molding portion that covers at least one of the oscillator 22 or the integrated circuit element 30 together with the substrate 31 with resin, and therefore, at least one of the oscillator 22 or the integrated circuit element 30 can be protected from an impact and a vibration from outside. Moreover, the rigidity of the substrate 31 is increased because of the molding portion, so that the external connection terminals 31d are less likely to be deflected due to an impact and a vibration. Therefore, in the piezoelectric vibration device 21, a distortion generated in the joined surface 31e between the external connection terminals 31d and the solder H due to an impact and a vibration from outside can be suppressed.

The solder H each is joined to the internal wiring 31c of the corresponding connection terminal 31d that is a raised portion that protrudes from the corresponding recessed portion 31g, the joined surface 31e, and a portion of the end surfaces 31f, and therefore, an area of a joined portion with the connection terminal 31d is increased, as compared to a case where the solder H is joined to only the joined surface 31e that is a plane surface. Therefore, with the oscillator 22 joined to the connection terminals 31d that are raised portions by the solder H, the oscillator 22 is more firmly joined to the substrate 31, as compared to a case where the oscillator mounting terminals 27a are joined to only the joined surfaces 31e. Thus, in the piezoelectric vibration device 21, separation of the oscillator 22 from the substrate 31 can be suppressed.

### Other Embodiments

In one of the embodiments described above, each of the recessed portions 11g of the substrate 11 is formed by recessing a portion of the substrate 11 in a range including a portion of a long side and a portion of a short side of the substrate 11 that are the outer edge of the substrate 11 when viewed in the Z-direction. However, the recessed portions of the substrate may not be in a range including the outer edge of the substrate. The recessed portions may be formed by recessing a portion of the substrate that does not include the outer edge of the substrate in an arbitrary shape when viewed in the Z-direction.

In one of the embodiments described above, the substrate 11 includes the recessed portion 11g for each one of the external connection terminals 11d. However, the substrate may not include the recessed portion for each external connection terminal. The substrate may be configured such that a plurality of external connection terminals are arranged in one recessed portion.

In one of the embodiments described above, the end surfaces 11fa and 11fb of the external connection terminals 11d each being adjacent to a corresponding one of the side surfaces 11i of the recessed portions 11g of the substrate 11 are located with the predetermined gap G provided between each of the end surfaces 11fa and 11fb and a corresponding one of the side surfaces 11i, when viewed in the Z-direction (see FIG. 6). However, end surfaces of the external connection terminals may be arranged such that a predetermined gap is provided between a side surface of each of the recessed portions and a portion of an end surface that is adjacent to the side surface, when viewed in the Z-direction.

In one of the embodiments described above, the recessed portions 11g of the substrate 11 are the same in thickness from the first mounting surface 11a to the bottom surface 11h. However, the recessed portions of the substrate may be different in thickness from the first mounting surface to the bottom surface.

In one of the embodiments described above, the substrate 11 includes the four recessed portions 11g. However, the substrate may include at least one recessed portion.

In one of the embodiments described above, each of the four end surfaces 11f including an outer edge of a corresponding one of the four external connection terminals 11d is located with a distance from the outer edge of the bottom surface 11h such that the predetermined gaps G1 and G2 are provided more inside in the recessed portion 11g than the outer edge of the bottom surface 11h, when viewed in the Z-direction. However, each of the end surfaces including the outer edge of the corresponding one of the four external connection terminals may be located with a distance from the outer edge of the bottom surface such that an arbitrary gap is provided more inside in the recessed portion than the outer edge of the bottom surface of the recessed portion, when viewed in the Z-direction.

In one of the embodiments described above, each of the internal wirings 11c is electrically connected to a corresponding one of the end surfaces 11f of the four external connection terminals 11d. However, each of the external connection terminals may be configured such that each of a plurality of internal wirings is exposed in the recessed portion and is electrically connected to a plurality of end surfaces of the external connection terminal.

In one of the embodiments described above, the oscillator 2 includes the through hole 4c between the frame portion 4 and the vibrating portion 5 and the vibrating portion 5 is cantilever-supported. However, the oscillator may have a configuration which does not include the through hole between the frame portion and the vibrating portion.

In one of the embodiments described above, the substrate 11 is formed of glass polyimide resin. However, a glass composite substrate of glass epoxy resin or the like, a fluororesin substrate, a ceramic substrate, or the like may be used for the substrate.

In one of the embodiments described above, the piezoelectric vibration device 1 includes the oscillator 2 having a three-layer structure in which the piezoelectric vibration plate 3, the first sealing member 7, and the second sealing member 8 are stacked. However, the piezoelectric vibration device may include an oscillator having a multi-layer structure including three or more layers. The oscillator may be a four-layer oscillator in which a sensor, such as a thermistor, is further mounted on the principal surface of the first sealing member.

In one of the embodiments described above, the piezoelectric vibration device 1 is configured such that the vibrating portion 5 or 17 is arranged in the internal space S of the piezoelectric vibration plate 3. However, the piezoelectric vibration device may be a piezoelectric vibration device having a so-called H-shaped structure that includes a bottom portion and frame-shaped side wall portions each being formed on a corresponding one of two opposed plane surfaces of the bottom portion to extend in a perpendicular direction to the plane surface. In the piezoelectric vibration device having the H-shaped structure, a piezoelectric element is arranged at an inner side of one of the side wall portions on one of the plane surfaces of the bottom portion. Moreover, in the piezoelectric vibration device having the H-shaped structure, an electronic component element is mounted at an inner side of the other one of the side wall portions on the other one of the plane surfaces of the bottom portion. The piezoelectric vibration device having the H-shaped structure is configured such that a first sealing member is joined to a tip end portion of the one of the side wall portions and a second sealing member is joined to a tip end portion of the other one of the side wall portions.

In one of the embodiments described above, the piezoelectric vibration plate 23 of the oscillator 22 includes the vibrating portion 24 separated from the piezoelectric vibration plate 23 to surround the pair of the excitation electrodes 24a with portions of the excitation electrodes 24a left non-surrounded. That is, the vibrating portion 24 is configured to have a cantilever structure in which the vibrating portion 24 is supported by the piezoelectric vibration plate 23 at one position. However, the vibrating portion may have a configuration in which the vibrating portion is supported by the piezoelectric vibration plate at a plurality of positions.

In one of the embodiments described above, each of the oscillators 2 and 22 is joined to a corresponding one of the substrates 11 and 31 by the solder H. However, the oscillator may be electrically or mechanically connected to the substrate. The oscillator may be joined to the substrate by, for example, a conductive adhesive or a die attach tape.

Embodiments of the present invention have been described above, but the above-described embodiments are merely illustrative examples for carrying out the present invention. Therefore, the present invention is not limited to the above-described embodiments and the above-described embodiments can be appropriately modified and implemented without departing from the gist of the present invention.

### REFERENCE SIGNS LIST

1, 21 Piezoelectric vibration device
2, 22 Oscillator
3, 23 Piezoelectric vibration plate
4 Frame portion
5, 24 Vibrating portion
5a First excitation electrode
5b Second excitation electrode
6 Connecting portion
7, 26 First sealing member
8, 27 Second sealing member
9 Protecting member
10, 30 Integrated circuit element
10a Integrated circuit element mounting terminal
11, 31 Substrate
11a, 31a First mounting surface
11b, 31b Second mounting surface
11c, 31c Internal wiring
11d External connection terminal
11e, 31e Joined surface
11f, 31f End surface
11g, 31g Recessed portion
11h, 31h Bottom surface
11i, 31i Side surface
12 Molding portion
13, 25 Joining material
24a Excitation electrode
25 Joining material
27a Oscillator mounting terminal
30 Integrated circuit element
S Internal space
G1, G2 Gap

1. A piezoelectric vibration device comprising:
an insulating substrate that includes a wiring pattern including a plurality of pads on one of a pair of principal surfaces, and an external connection terminal electrically connected to the wiring pattern and electrically connected to an external substrate on the other one of the principal surfaces extending in parallel to the one of the principal surfaces; and
at least a piezoelectric oscillator and an integrated circuit element including an oscillation circuit that are mounted on the insulating substrate,
wherein
the insulating substrate includes a recessed portion in the other one of the principal surfaces, and
the external connection terminal is arranged in the recessed portion and is configured such that a gap is provided between an outer edge of the external connection terminal and a side surface of the recessed portion.

2. The piezoelectric vibration device according to claim 1, wherein the external connection terminal is arranged in the recessed portion with a predetermined space from an outer edge of the recessed portion provided, when viewed in a perpendicular direction to the other one of the principal surfaces.

3. The piezoelectric vibration device according to claim 1, wherein a thickness from the one of the principal surfaces to a joined surface that is electrically connected to the external substrate in the external connection terminal is less than a thickness from the one of the principal surfaces to the other one of the principal surfaces.

4. The piezoelectric vibration device according to claim 1, wherein the insulating substrate is configured such that at least one of the piezoelectric oscillator or the integrated circuit element on the one of the principal surfaces is partially or entirely covered with resin.

5. The piezoelectric vibration device according to claim 1, wherein the insulating substrate is configured such that a portion of an internal wiring electrically connecting the wiring pattern and the external connection terminal is not covered with a base material of the insulating substrate and is exposed, the portion of the internal wiring being located at the other one of the principal surfaces.

6. The piezoelectric vibration device according to claim 1, wherein the oscillator and the integrated circuit element are arranged on a same mounting surface of the insulating substrate.
